(19) United States
(12) Patent Application Publication
(10) Pub. No.: US 2011/0133612 A1
(43) Pub. Date: Jun. 9, 2011

(54) PORTABLE ELECTRONIC DEVICE WITH PENDANT MOUNTING STRUCTURE

(75) Inventors: JIAN-HUI CHEN, Shenzhen City (CN); JUN-FANG LIU, Shenzhen City (CN); MING-ZHI ZHENG, Shenzhen (CN)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/791,055

(22) Filed: Jun. 1, 2010

(30) Foreign Application Priority Data
Dec. 7, 2009 (CN) 200920316708.2

(51) Int. Cl. H05K 5/03

(52) U.S. Cl. 312/223.1

(57) ABSTRACT

A portable device comprises a main body, a cover, a pendant mounting structure. The cover is mounted to the main body. The pendant mounting structure is coupled between the main body and the cover, the pendant mounting structure includes a mounting space and a post that engages with the mounting space. When the cover is mounted to the main body, a retaining hole is defined between the mounting space and the post for retaining a hanger element on the device.

### BACKGROUND

1. Technical Field

The exemplary disclosure generally relates to portable electronic devices, particularly to portable electronic devices with a pendant mounting structure.

2. Description of Related Art

Mobile phones may have a decorative pendants attached to them. The pendants generally hang from a hanger element, such as a string or chain looped through a dedicated hole ligament of the mobile phone.

However, it is difficult to thread the hanger element through the hole as the hole is usually small. In addition, if the hanger element is pulled on with enough force, rather than the hanger element breaking, the housing may be damaged.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary portable electronic device with a pendant mounting structure. Moreover, in the drawings like reference numerals designate corresponding parts throughout the several views. Wherever possible, the same reference numbers are used throughout the drawings to refer to the same or like elements of an embodiment.

FIG. 1 is an assembled view of an exemplary embodiment of portable electronic device with a pendant mounting structure.

FIG. 2 is an exploded view of the portable electronic device shown in FIG. 1.

FIG. 3 is a cross-sectional view of the portable electronic device shown in FIG. 1.

### DETAILED DESCRIPTION

In this exemplary embodiment, the device is an electronic device such as a mobile telephone but most any device with a pendant is suitable for this disclosure. Accordingly, any reference herein to the mobile telephone should also be considered to apply equally to other portable devices.

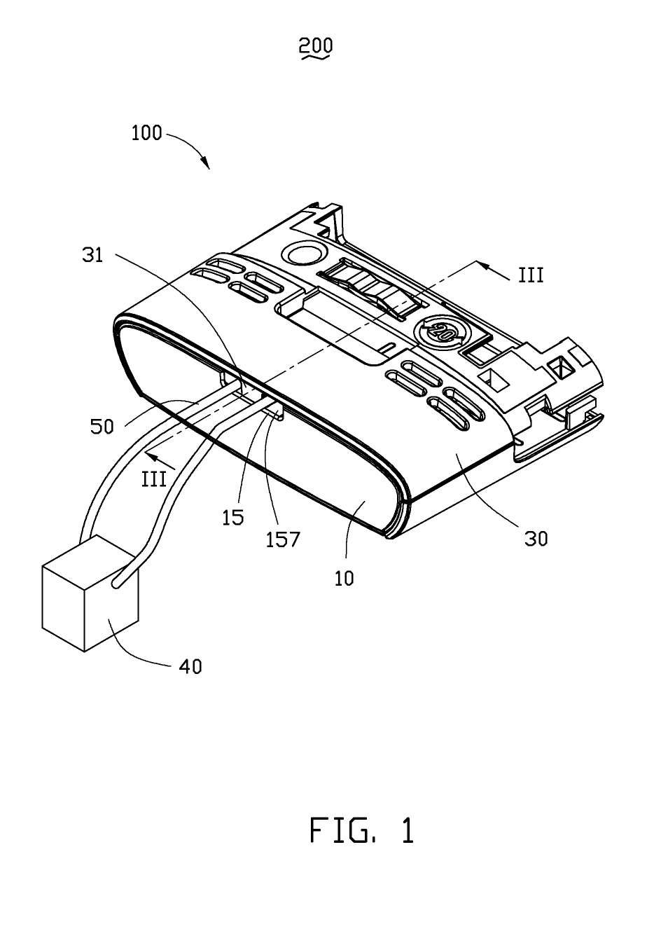

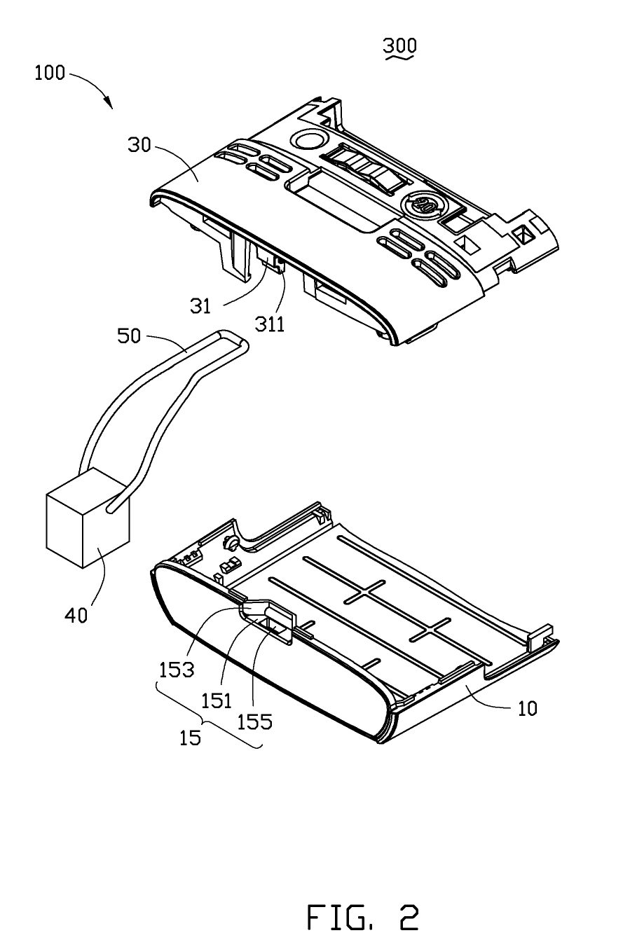

An embodiment of a device 100 incorporating a pendant mounting structure (not labeled) is shown in FIG. 1 and FIG. 2. FIG. 1 illustrates an assembled view of the device 100 in a closed configuration 200. FIG. 2 illustrates an exploded view of the device 100 in an opened configuration 300.

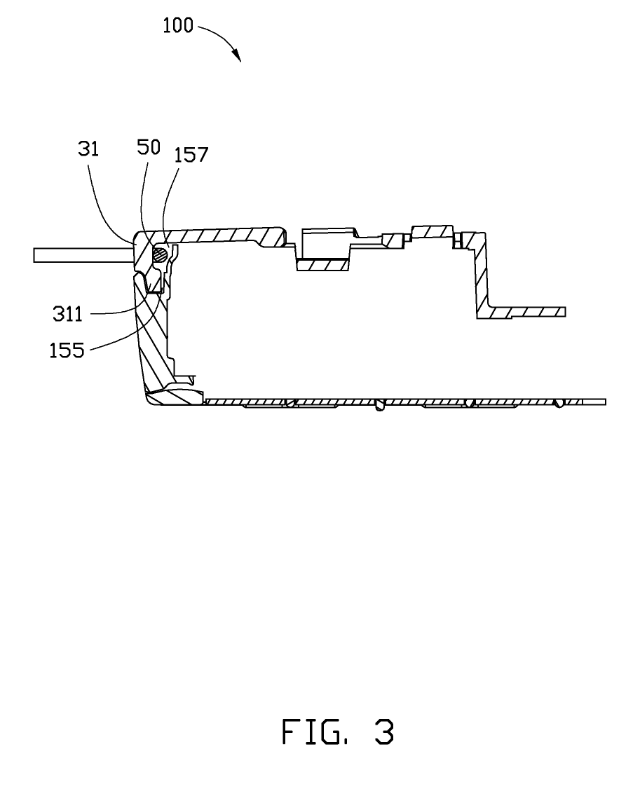

The exemplary device 100 includes a main body 10, a cover 30 mounted to the main body 10, and the pendant mounting structure coupled between the main body 10 and the cover 30. The pendant mounting structure provides a mechanism for hanging a hanger element 50 of a pendant 40. The pendant mounting structure may include a mounting space 15 and a post 31 that engages in the mounting space 15. When the cover 30 is mounted to the main body 10, i.e., the device 100 is in the closed configuration 200, a retaining hole 157 (clearly seen in FIG. 3) is defined between the mounting space 15 and the post 31 for retaining the hanger element 50 on the device 100.

In this exemplary embodiment, the mounting space 15 is positioned on the main body 10 and is defined by a planar wall 151 and a sidewall 153 protruding from the planar wall 151. The post 31 is positioned on the cover 30 facing the planar wall 151. When the device 100 is in the closed configuration 200, the post 31 is located in the mounting space 15 and is spaced from the sidewall 153 such that the retaining hole 157 is defined between the post 31 and the sidewall 153. It is to be understood that the mounting space 15 may be defined in either the main body 10 or the cover 30, and the mounting space 15 engaging member (e.g. post 31) may be positioned on the element that the mounting space 15 is not defined in.

The pendant mounting structure further includes a stopping member (not labeled) which prevents the pendant mounting structure from bending or breaking when the hanger element is dragged through retaining hole 157 by manual force. The stopping member, in this embodiment, may include a latching receptacle 155 defined in the planar wall 151 of the mounting space 15 and a latching portion 311 protruding from a distal end of the post 31. When the device 100 is in the closed configuration 200, the latching portion 311 is located in the latching receptacle 155 and resists the sidewall of the latching receptacle 155 to prevent the distal end of the post 31 from moving away from the sidewall 153 of the mounting space 15, i.e., preventing the post 31 from bending or being otherwise damaged. If the hanger element 50 is pulled, the stopping member acts as a strengthening mechanism for strengthening the pendant mounting structure in such a manner that the pulling force is simultaneously delivered to the cover 30 and the main body 10 so that the post 31 does not have to bear all the force and be easily damaged.

In use, the hanger element 50 is first positioned in the mounting space 15. The latching portion 311 of the post 31 is then aligned with the latching receptacle 155 of the mounting space 15. The cover 30 is mounted to the main body 10 with the latching portion 311 latched in the latching receptacle 155 and the post 31 located in the mounting space 15, such that the retaining hole 157 is defined between the post 31 and the mounting space 15, i.e., the hanger element 50 is retained in the retaining hole 157. To remove the hanger element 50 from the device 100, the cover 30 is separated from the main body 10 to open the device 100 to the configuration 300 shown in FIG. 2. With this motion, the latching portion 311 is slid out of the latching receptacle 155 and the post 31 is slid out of the mounting space 15, thereby the hanger element 50 can be easily removed from the device 100.

It is to be understand that the pendant mounting structure may be used in another way, like as: the latching portion 311 of the post 31 is first aligned with the latching receptacle 155 of the mounting space 15; The cover 30 is mounted to the main body 10 with the latching portion 311 latched in the latching receptacle 155 and the post 31 located in the mounting space 15, such that the retaining hole 157 is defined between the post 31 and the mounting space 15; the hanger element 50 is then threaded or looped through retaining hole 157 and attached to the pendant 40.

It is to be understood, however, that even through numerous characteristics and advantages of the exemplary invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A portable device, comprising:
a main body;
a cover mounted to the main body;
a pendant mounting structure coupled between the main body and the cover, the pendant mounting structure including a mounting space and a post that engages with the mounting space;
wherein when the cover is mounted to the main body, a retaining hole is defined between the mounting space and the post is configured for retaining a hanger element on the device.

2. The device as claimed in claim 1, wherein the mounting space is defined on the main body, the post is positioned on the cover.

3. The device as claimed in claim 2, wherein the mounting space is defined by a planar wall and a sidewall protruding from the planar wall, when the cover is mounted to the main body, the post is located in the mounting space and is spaced from the sidewall to define the retaining hole between the post and the sidewall.

4. The device as claimed in claim 3, wherein the post faces the planar wall of the mounting space.

5. The device as claimed in claim 3, wherein the pendant mounting structure further includes a stopping member which prevents the pendant mounting structure from bending or breaking when the hanger element is dragged through retaining hole by manual force.

6. The device as claimed in claim 5, wherein the stopping member include a latching receptacle defined in the planar wall of the mounting space and a latching portion protruding from a distal end of the post; the latching portion is located in the latching receptacle when the cover is mounted to the main body.

7. The device as claimed in claim 6, wherein the latching portion is configured to resist the sidewall of the latching receptacle to prevent the distal end of the post from moving away from the sidewall of the mounting space.

8. A portable device, comprising:
a main body defining a mounting space formed by a planar wall and a sidewall protruding from the planar wall;
a cover mounted to the main body, wherein the cover includes a post facing the planar wall of the main body and spaced from the sidewall of the main body, a retaining hole is defined between the sidewall of the main body and the post for retaining a hanger element to the device;
wherein the planar wall of the main body has a latching receptacle defined therein; a latching portion protrudes from a distal end of the post, the latching portion extends into the latching receptacle when the cover is mounted to the main body, such that when the hanger element is dragged by an external force through the retaining hole, the external force is simultaneously delivered to the cover and the main body to prevent the post from damage.
